(19) United States
(12) Patent Application Publication
(10) Pub. No.: US 2006/0144988 A1
(43) Pub. Date: Jul. 6, 2006

(54) Device and method for transporting film carrier tape for mounting electronic components

(75) Inventors: Takashi Mitsui, Yamaguchi (JP); Sachio Noto, Gifu (JP)

Correspondence Address: THE WEBB LAW FIRM, P.C., 700 KOPPERS BUILDING, 436 SEVENTH AVENUE, PITTSBURGH, PA, 15219, US

(73) Assignees: Mitsui Mining & Smelting Co., Ltd., Shinagawa-ku (JP); Kamioka Mining Engineering Co., Ltd., Hida-shi (JP)

(21) Appl. No.: 10/546,494

(22) PCT Filed: Feb. 18, 2004
(86) PCT No.: PCT/JP04/01815

§ 371 Date: Aug. 22, 2005

(30) Foreign Application Priority Data
Feb. 20, 2003 (JP) 2003-042960

(51) Int. Cl. B65H 20/20; H01L 21/60

(52) U.S. Cl. 242/412.1; 242/334.6

(57) ABSTRACT

A transportation apparatus for a film carrier tape for mounting electronic components comprises an unwinding side tension applying means 21 for applying a tension on the unwinding side to the film carrier tape 3, and a winding side tension applying means 23 for applying more larger tension on the winding side to the film carrier tape 3 than the tension on the unwinding side, and thereby the film carrier tape 3 is transported in such a condition that the gear protrusions 31 of the drive gear 17 are not abutted with the edges of the transportation direction side in the sprocket holes 40 of the film carrier tape 3. In another embodiment, the presser roll 19 in the transportation driving part 15 is disposed in such a state that the shaft of the presser roll 19 is tilted with a predetermined angle in the transportation direction with respect to the shaft of the drive gear 17, and thereby the film carrier tape 3 is transported in such a condition that the film carrier tape 3 is abutted with both the drive roll surface of the drive gear 17 and the presser roll surface of the presser roll 19 at a surface.

### TECHNICAL FIELD

The present invention relates to a transportation apparatus for transporting film carrier tapes for mounting electronic components formed with conductive wiring patterns on an insulating film (such as TAB (Tape Automated Bonding) tape, T-BGA (Tape Ball Grid Array) tape, CSP (Chip Size Package) tape, ASIC (Application Specific Integrated Circuit) tape, COF (Chip on Film) tape, 2-metal (double-sided wiring) tape, multilayer wiring tape or the like) (hereinafter referred to simply as “film carrier tape for mounting electronic components”) in treatment steps such as inspection step and other steps, and also relates to a transportation process for the tapes.

### TECHINCAL BACKGROUND

In the electronics industrial fields, printed wiring boards for mounting electronic components such as IC (integrated circuit), LSI (large scale integrated circuit) and the like have been used. Nowadays, electronic apparatuses typified by, for example, mobile phones have been desired to have downsizing and decrease in weight, high functionalizing, high reliability, decrease in cost and the like.

As a method of mounting electronic components for realizing such properties of electronic apparatuses such as downsizing and decrease in weight, or the like, a device is mounted on a film carrier tape for mounting electronic components such as TAB tapes or the like. The film carrier tape for mounting such electronic components is prepared by the following manner. To an insulating film such as polyimide, etc, a conductive metal foil such as copper foil, etc is adhered through a resin adhesive such as epoxy, etc, a photosensitive resin is applied on the surface of the conductive metal foil and developed with exposure so as to prepare a desired wiring pattern, and thereafter, the conductive metal foil is etched using the exposed parts or un-exposed parts of the resin as a masking material to form a wiring pattern, followed by carrying out application with a solder resist, curing, and plating treatment.

Recently, during the downsizing and decrease in weight of the electronic apparatuses have been desired as described above, the high density mounting of the electronic components, further, has been desired, and narrowing of pitch in the wiring of a film carrier tape for mounting electronic components and thinning of the film thickness have been progresses accompanying these demands.

Under such circumstances, a two layered flexible substrate prepared by directly forming a copper conductive layer on an insulating film by, for example, a procedure of copper electrodeposition to form a thin plating layer on an insulating film has been developed and used for COF (Chip on Film) tape and like.

As is shown in FIG. 9, on a film carrier tape 103 for mounting electronic components such as COF, etc, units 142, 142 . . . for mounting electronic components each having a conductive wiring pattern formed thereon are formed in a tape longitudinal direction. On the both ends of the width direction of the tape, sprocket holes 140, 140, . . . provided for transportation are in parallel perforated in a longitudinal direction. The tape width is usually about from 35 to 200 mm, and the length of the side of the sprocket hole 140 is usually about from 1.42 to 1.98 mm.

The film carrier tape 103 for mounting electronic components passed through the production step is inspected in a inspection step by discerning defects caused in conductive wiring patterns of each of units 142, 142 . . . for mounting electronic components and then making punching with perforating defective units or making marking with an ink mark to a defective unit by means of ink marking and other means, and then submitted to use.

In this inspection step, for example, marking is made in a defective unit in such a way that each of units 142, 142 . . . for mounting electronic components present in a film carrier tape 103 for mounting electronic components is transported through a prescribed treatment part (referred to, for example, JP-A-2001-358180) and only a defective unit is selected from these units and marked.

The schematic structure of a transportation apparatus conventionally used for transporting in the inspection step of a film carrier tape 103 for mounting electronic components is shown in FIG. 10. This transportation apparatus 101 is equipped with an unwinding reel 105 for unwinding the film carrier tape 103 for mounting electronic components, a treatment part 113 for carrying out a prescribed treatment such as inspection, marking or the like to the film carrier tape 103 unwound from the unwinding reel 105 and a winding reel 107 for winding the film carrier tape 103 treated with the prescribed treatment in the treatment part 113. The referential numerals 109 and 111 show guide rolls for leading the film carrier tape 103 so as to transport the film carrier tape 103 in a horizontal direction in the treatment part 113 and the referential numerals 125 and 127 show guide rolls for leading the film carrier tape 103.

On the upstream side in the transporting direction of the treatment part 113, a back tension part 129 is provided, while on the downstream side in the transporting direction, a transportation driving part 115 is provided.

As shown in FIG. 11, the transportation driving part 115 is provided with a drive gear 117 and a presser roll 119. The drive gear 117 is provided in such a way that the drive roll surface is abutted to the surface of the film carrier tape 103 from the back side thereof, and gear protrusions 131, 131 . . . provided in the both ends of the drive roll surface in line are engaged with sprocket holes 140, 140 . . . of the film carrier tape 103 and thereby the film carrier tape 103 is transported.

The presser roll 119 is abutted to the drive roll surface of the drive gear 117 on the presser roll surface so as to hold the film carrier tape 103.

The back tension part 129 is consisted of, for example, a pair of rolls disposed in such a way that the film carrier tape 103 is held from the up side and down side thereof with the roll surfaces and operates as follows. The carrier tape 103 is held with both of the roll surfaces, and a tension is applied on the film carrier tape 103 to a direction opposite to the transportation direction thereof by driving of the transportation driving part 115 so as to transport the film carrier tape 103 straightly and stably.

However, in the conventional transportation apparatuses, as described above, since a tension is applied on the film carrier tape 103 to a direction opposite to the transportation direction thereof in the back tension part 129, in the transportation driving part 115, as shown in FIG. 11, the gear protrusions 131, 131 . . . of the drive gear 117 are engaged in such a condition that the gear protrusions are abutted with the ends 144 in the transportation direction side of the sprocket holes 140, 140 . . . and thereby the film carrier tape 103 is transported. Therefore, when the gear protrusion 131 engaged is come out from the sprocket hole 140 with rotation of the drive gear 117, the gear protrusion is rubbed with the ends 144 in the transportation direction side of the sprocket hole 140 to cause such problems that whenever the engagement thereof is come out, noises such as crunch or the like are caused and give unpleasantness to operators in inspection or the ends 144 of the sprocket holes 140 are deformed or broken.

Furthermore, the conventional transportation apparatuses have the following problems. As shown in FIG. 11, since the shaft of the presser roll 119 is provided in the direction vertical to the transportation direction toward the shaft of the drive gear 117, the transportation is carried out in such a condition that the film carrier tape 113, the drive roll surface of the drive gear 117 and the presser roll surface of the presser roll 119 are contacted at a point. On this account, the transportation becomes unstable to cause problems as follows. For example, when the roll is shaky, the gear protrusions 131 engaged with the sprocket holes 140 will catch and intrude into the film carrier tape 103 and harm the sprocket holes 140 also used for positioning, or optionally harm wiring patterns.

Each of the above problems is easily caused in transporting, particularly, COF tapes having a thin film thickness and comparatively weak strength among the film carrier tapes for mounting electronic components.

The present invention is intended to solve the above problems, and it is an object of the present invention to provide a transportation apparatus for a film carrier tape for mounting electronic components capable of transporting stably without damaging the film carrier tape for mounting electronic components, and a process for transporting the film carrier tape.

### DISCLOSURE OF THE INVENTION

The transportation apparatus for a film carrier tape for mounting electronic components according to the present invention comprises:

an unwinding reel for unwinding a film carrier tape for mounting electronic components,

a treatment part for treating a prescribed treatment to the film carrier tape unwound from the unwinding reel,

a winding reel for winding the film carrier tape treated in the treatment part, and

a transportation driving part equipped with a drive gear having a plurality of gear protrusions for transporting the film carrier tape by engaging with sprocket holes formed on the film carrier tape, and further comprises

an unwinding side tension applying means for applying a tension on the unwinding side to the film carrier tape which means is provided between the unwinding reel and the treatment part, and

a winding side tension applying means for applying a tension on the winding side to the film carrier tape which means is provided between the winding reel and the treatment part,

wherein the tension applied by the winding side tension applying means is larger than the tension applied by the unwinding side tension applying means, and thereby

the film carrier tape is transported in such a condition that the gear protrusions of the drive gear are not abutted with the edges of the transportation direction side in the sprocket holes of the film carrier tape.

Using the transportation apparatus having such a structure, the film carrier tape for mounting electronic components can be stably transported without damaging the film carrier tape.

In the above invention, the unwinding side tension applying means and the winding side tension applying means can be formed so that a tension can be applied on the film carrier tape by the self-weight thereof. That is, they have a structure such that the self-weight of the winding side tension applying means is heavier than the self-weight of the unwinding side tension applying means, and thereby the film carrier tape can be transported in such a condition that the gear protrusions of the drive gear are not abutted with the edges on the transportation direction side in the sprocket holes of the film carrier tape.

In the case of the transportation apparatus having such a structure that a tension is applied on film carrier tapes by the self-weight, it is preferred to use a dancer roll as the unwinding side tension applying means and the winding side tension applying means from the viewpoint of transporting the film carrier tape stably.

The transportation apparatus for a film carrier tape for mounting electronic components according to the present invention comprises:

an unwinding reel for unwinding a film carrier tape for mounting electronic components,

a treatment part for treating a prescribed treatment to the film carrier tape unwound from the unwinding reel,

a winding reel for winding the film carrier tape treated in the treatment part, and

a transportation driving part equipped with a drive gear having a plurality of gear protrusions for transporting the film carrier tape by engaging with sprocket holes formed on the film carrier tape,

wherein the drive gear is equipped with a drive roll surface and

the transportation driving part is equipped with a presser roll having a presser roll surface capable of holding the film carrier tape by abutting with the drive roll surface of the drive gear,

the presser roll is disposed in such a state that the shaft of the presser roll is tilted with a predetermined angle in the transportation direction with respect to the shaft of the drive gear, and thereby

the film carrier tape is transported in such a condition that the film carrier tape is abutted with the drive roll surface of the drive gear at a surface on the upstream side in the transportation direction from the contact point of the drive gear with the presser roll, and

the film carrier tape is abutted with the presser roll surface of the presser roll at a surface on the downstream side in the transportation direction from the contact point of the drive gear with the presser roll.

Using the transportation apparatus having such a structure, the film carrier tape for mounting electronic components can be stably transported.

The transportation apparatus for a film carrier tape for mounting electronic components according to the present invention comprises:

an unwinding reel for unwinding a film carrier tape for mounting electronic components,

a treatment part for treating a prescribed treatment to the film carrier tape unwound from the unwinding reel,

a winding reel for winding the film carrier tape treated in the treatment part, and

a transportation driving part equipped with a drive gear having a plurality of gear protrusions for transporting the film carrier tape by engaging with sprocket holes formed on the film carrier tape, and further comprises

an unwinding side tension applying means for applying a tension on the unwinding side to the film carrier tape which means is provided between the unwinding reel and the treatment part, and

a winding side tension applying means for applying a tension on the winding side to the film carrier tape which means is provided between the winding reel and the treatment part,

wherein the tension applied by the winding side tension applying means is larger than the tension applied by the unwinding side tension applying means, and thereby

the film carrier tape is transported in such a condition that the gear protrusions of the drive gear are not abutted with the edges of the transportation direction side in the sprocket holes of the film carrier tape, and further,

the drive gear is equipped with a drive roll surface and

the transportation driving part is equipped with a presser roll having a presser roll surface capable of holding the film carrier tape by abutting with the drive roll surface of the drive gear,

the presser roll is disposed in such a state that the shaft of the presser roll is tilted with a predetermined angle in the transportation direction with respect to the shaft of the drive gear, and thereby

the film carrier tape is transported in such a condition that the film carrier tape is abutted with the drive roll surface of the drive gear at a surface on the upstream side in the transportation direction from the contact point of the drive gear with the presser roll, and

the film carrier tape is abutted with the presser roll surface of the presser roll at a surface on the downstream side in the transportation direction from the contact point of the drive gear with the presser roll.

Using the transportation apparatus having such a structure, the film carrier tape for mounting electronic components can be extremely stably transported without damaging the film carrier tape for mounting electronic components.

In the above invention, the unwinding side tension applying means and the winding side tension applying means can be formed to have a structure such that a tension is applied to the film carrier tape by the self-weight thereof. That is, they are formed so that the self-weight of the winding side tension applying means is heavier than the self-weight of the unwinding side tension applying means and thereby the film carrier tape can be transported in such a condition that the gear protrusions of the drive gear are not abutted with the edges of the transportation direction side in the sprocket holes of the film carrier tape.

In the transportation apparatus for a film carrier tape for mounting electronic components having a structure such that a tension is applied to the film carrier tape by the self-weight, it is preferred to use a dancer roll as the unwinding side tension applying means and the winding side tension applying means from the viewpoint of transporting the film carrier tape stably.

The process for transporting a film carrier tape for mounting electronic components according to the present invention is characterized by using a transportation apparatus for a film carrier tape for mounting electronic components which apparatus comprises:

an unwinding reel for unwinding a film carrier tape for mounting electronic components,

a treatment part of treating a prescribed treatment to the film carrier tape unwound from the unwinding reel,

a winding reel for winding the film carrier tape treated in the treatment part, and

a transportation driving part equipped with a drive gear having a plurality of gear protrusions for transporting the film carrier tape by engaging with sprocket holes formed on the film carrier tape, which process comprises the steps of:

applying a tension on the unwinding side to the film carrier tape by an unwinding side tension applying means provided between the unwinding reel and the treatment part,

applying a tension to the winding side to the film carrier tape by a winding side tension applying means provided between the winding reel and the treatment part,

wherein the tension applied by the winding side tension applying means is larger than the tension applied by the unwinding side tension applying means, and thereby

transporting the film carrier tape in such a condition that the gear protrusions of the drive gear are not abutted with the edges of the transportation direction side in the sprocket holes of the film carrier tape.

By such a process, the film carrier tape for mounting electronic components can be stably transported without damaging the film carrier tape.

The process for transporting a film carrier tape for mounting electronic components according to the present invention is characterized by using a transportation apparatus for a film carrier tape for mounting electronic components which apparatus comprises:

an unwinding reel for unwinding a film carrier tape for mounting electronic components,

a treatment part for treating a prescribed treatment to the film carrier tape unwound from the unwinding reel,

a winding reel for winding the firm carrier tape treated in the treatment part, and

a transportation driving part equipped with a drive gear having a plurality of gear protrusions for transporting the film carrier tape by engaging with sprocket holes formed on the film carrier tape,

wherein the drive gear is equipped with a drive roll surface and

the transportation driving part is equipped with a presser roll having a presser roll surface capable of holding the film carrier tape by abutting with the drive roll surface of the drive gear,

the presser roll is disposed in such a state that the shaft of the presser roll is tilted with a predetermined angle in the transportation direction with respect to the shaft of the drive gear, and thereby

the film carrier tape is transported in such a condition that the film carrier tape is abutted with the drive roll surface of the drive gear at a surface on the upstream side in the transportation direction from the contact point of the drive gear with the presser roll, and

the film carrier tape is abutted with the presser roll surface of the presser roll at a surface on the downstream side in the transportation direction from the contact point of the drive gear with the presser roll.

By such a process, the film carrier tape for mounting electronic components can be stably transferred.

The process for transporting a film carrier tape according to the present invention is characterized by using a transportation apparatus for a film carrier tape for mounting electronic components which apparatus comprises:

an unwinding reel for unwinding a film carrier tape for mounting electronic components,

a treatment part for treating a prescribed treatment to the film carrier tape unwound from the unwinding reel,

a winding reel for winding the film carrier tape treated in the treatment part, and

a transportation driving part equipped with a drive gear having a plurality of gear protrusions for transporting the film carrier tape by engaging with sprocket holes formed on the film carrier tape,

which process comprises the steps of:

applying a tension on the unwinding side to the film carrier tape by an unwinding side tension applying means provided between the unwinding reel and the treatment part,

applying a tension on the winding side to the film carrier tape by a winding side tension applying means provided between the winding reel and the treatment part,

wherein the tension applied by the winding side tension applying means is larger than the tension applied by the unwinding side tension applying means, and thereby

transporting the film carrier tape in such a condition that the gear protrusions of the drive gear are not abutted with the edges of the transportation direction side in the sprocket holes of the film carrier tape, and further,

the drive gear is equipped with a drive roll surface and

the transportation driving part is equipped with a presser roll having a presser roll surface capable of holding the film carrier tape by abutting with the drive roll surface of the drive gear,

the presser roll is disposed in such a state that the shaft of the presser roll is tilted with a predetermined angle in the transportation direction with respect to the shaft of the drive gear, and thereby

the film carrier tape is transported in such a condition that the film carrier tape is abutted with the drive roll surface of the drive gear at a surface on the upstream side in the transportation direction from the contact point of the drive gear with the presser roll, and

the film carrier tape is abutted with the presser roll surface of the presser roll at a surface on the downstream side in the transportation direction from the contact point of the drive gear with the presser roll.

By such a process, the film carrier tape can be extremely stably transported without damaging the carrier tape.

### BRIEF DESCRIPITON OF THE DRAWINGS

FIG. 1 is a schematic view showing one embodiment of a transportation apparatus for a film carrier tape for mounting electronic components according to the present invention.

FIG. 2 is a partially enlarged view of a transportation driving part in the embodiment shown in FIG. 1.

FIG. 3 is a schematic view showing another embodiment of a transportation apparatus for a film carrier tape for mounting electronic components according to the present invention.

FIG. 4 is a partially enlarged view of a transportation driving part in the embodiment shown in FIG. 3.

FIG. 5 is a schematic view showing another embodiment of a transportation apparatus for a film carrier tape for mounting electronic components according to the present invention.

FIG. 6 is a partially enlarged view of a transportation driving part in the embodiment shown in FIG. 5.

FIG. 7 is a schematic view showing one embodiment of the structure of a presser roll according to the present invention.

FIG. 8 is a schematic view showing another embodiment of the structure of a presser roll according to the present invention.

FIG. 9 is a schematic view showing apart of a film carrier tape for mounting electronic components.

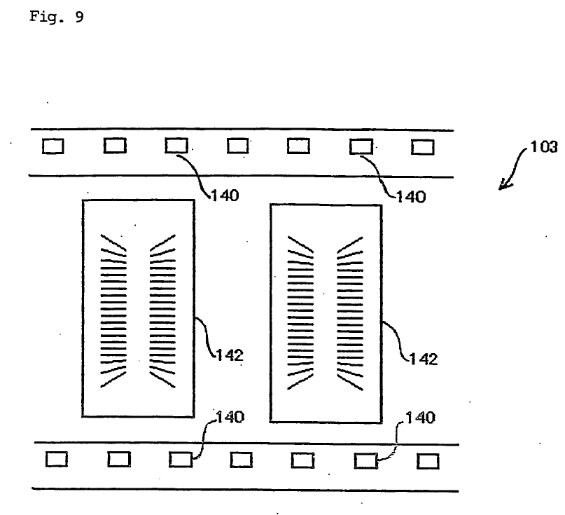

FIG. 10 is a schematic view showing a conventional transportation apparatus for a film carrier tape for mounting electronic components.

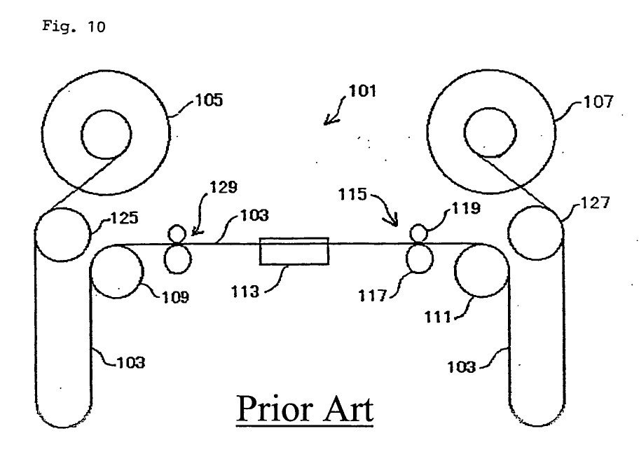

FIG. 11 shows a partially enlarged view showing a transportation driving part in a transportation apparatus shown in FIG. 10.

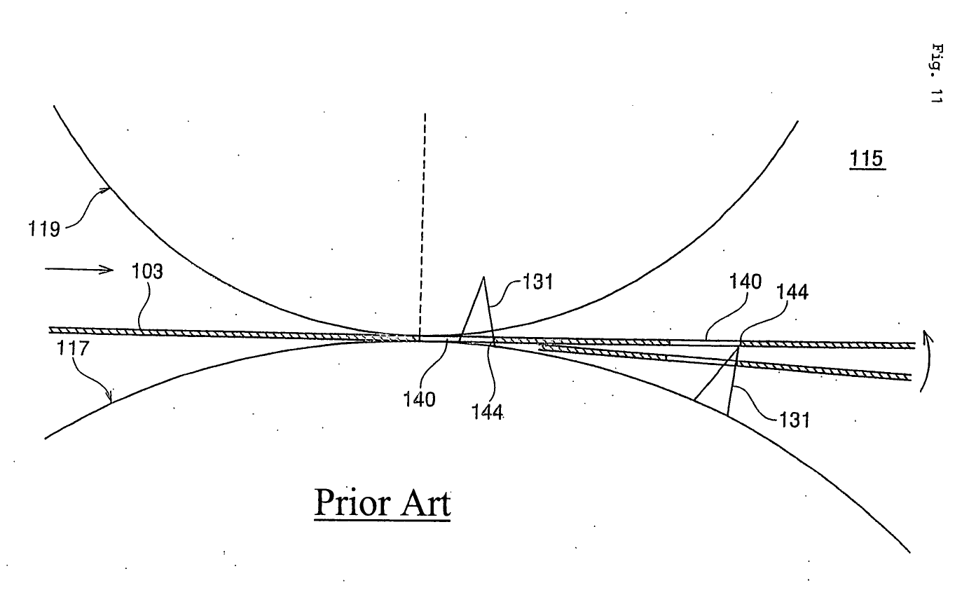

### BEST EMBODIMENT FOR CARRYING OUT THE INVENTION

Hereinafter, the present invention will be described in detail with reference to the drawings.

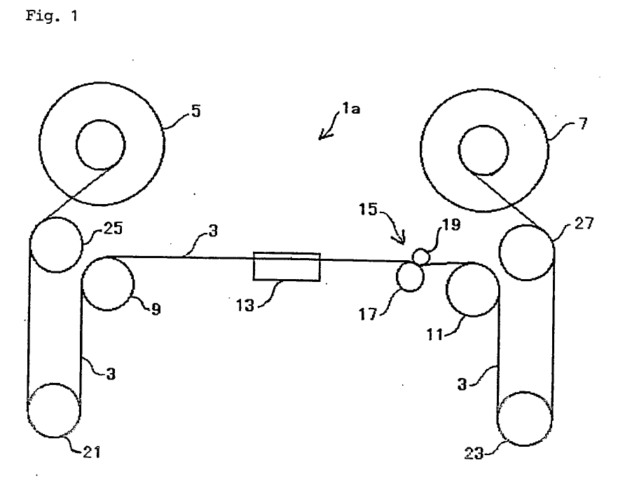

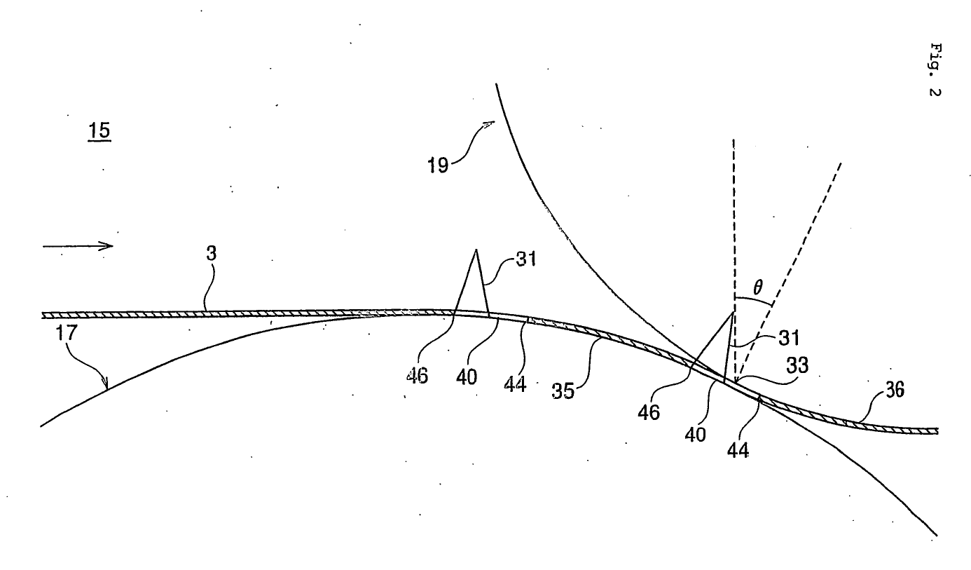

FIGS. 1, 3 and 5 each show a schematic structural view showing an embodiment of a transportation apparatus for a film carrier tape for mounting electronic components according to the present invention and FIGS. 2, 4 and 6 each shows a partially enlarged view showing the transportation part thereof.

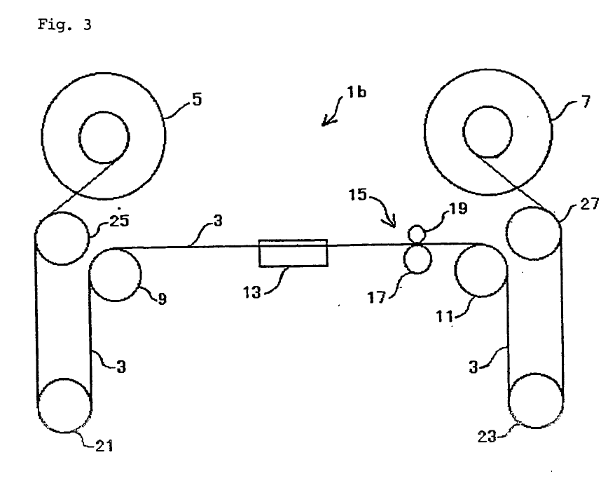

The transportation apparatus 1b of the film carrier tape for mounting electronic component as shown in FIG. 3 is equipped with

an unwinding reel 5 for unwinding a film carrier tape 3 for mounting electronic components,

a treatment part 13 for treating a prescribed treatment to the film carrier tape 3 unwound from the unwinding reel 5, for example, failure distinction treatment or failure marking treatment and

a winding reel 7 for winding the film carrier tape 3 treated in the treatment part 13. The referential numerals 9 and 11 each show a guide roll for guiding the film carrier tape 3 so that the film carrier tape 3 is horizontally transported in the treatment part 13, and the referential numerals 25 and 27 also each show a guide roll for guiding the film carrier tape 3. The film carrier tape 3 for treatment in the present invention has a tape width of from 35 to 200 mm, and a tape thickness of from 10 to 125 μm, preferably 25 to 75 μm.

Further, a transportation driving part 15 is provided on the downstream side of the treatment part 13 in the transportation direction.

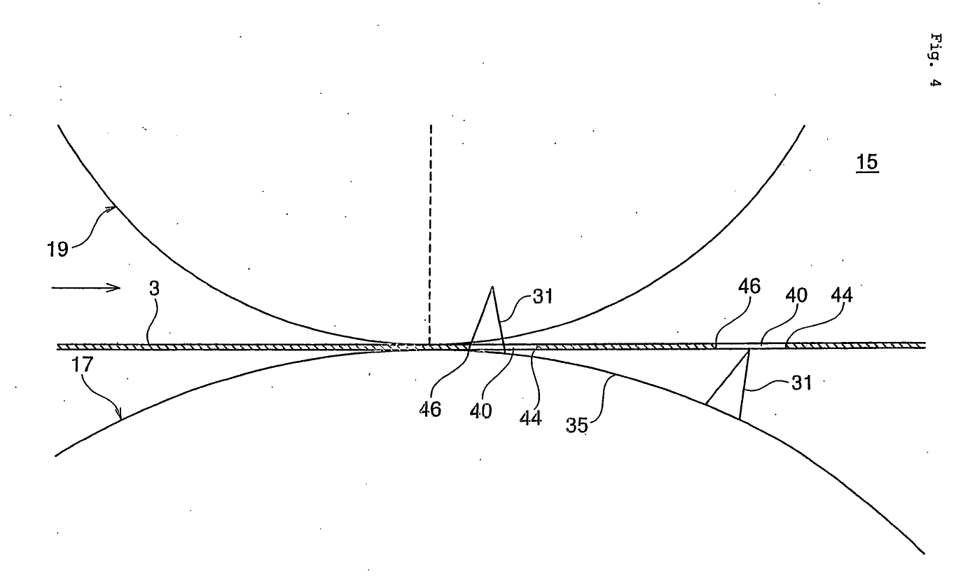

The transportation driving part 15, as shown in FIG. 4, is equipped with a drive gear 17 and a presser roll 19. The drive gear 17 is provided so that the drive roll surface is abutted with the surface of the film carrier tape 3 from the down side, gear protrusions 31, 31, . . . provided in the both ends of the drive roll surface in line are engaged with sprocket holes 40, 40, . . . of the film carrier tape 3 and thereby the film carrier tape 3 is transported.

The presser roll 19 is abutted with the drive roll surface of the drive gear 17 on the presser roll surface to hold the film carrier tape 3.

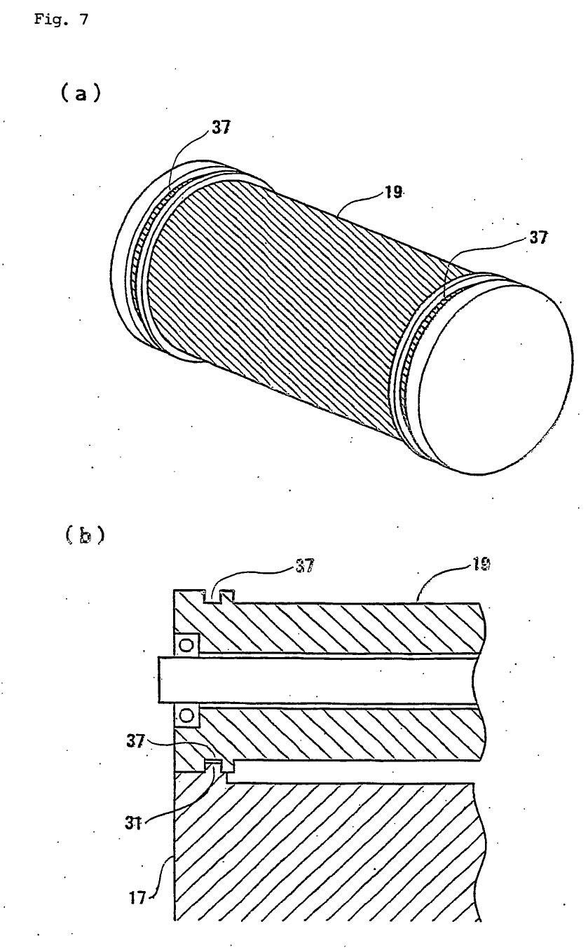

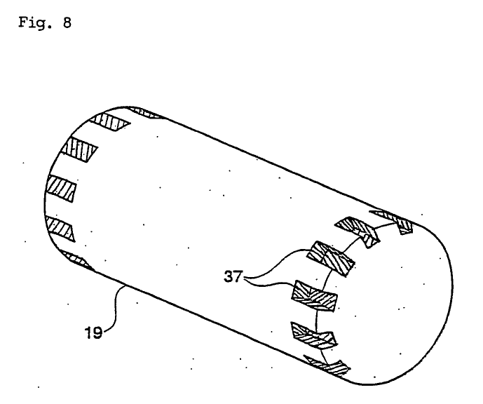

As shown in FIG. 7 (a), in the presser roll 19, it is preferred to provide notch grooves 37 having the almost same width as that of the gear protrusions 31, 31, . . . over the round on both ends of the roll surface. As shown in FIG. 7 (b), providing the notch grooves 37, at the time of driving of the drive gear 17, the gear protrusions 31 rotate in such a condition that they are introduced into the notch grooves 37 through the sprocket holes 40 and the presser roll 19 holds the film carrier tape 3 on the both sides of the notch grooves 37 and thereby the sprocket holes 40 hardly come out from the gear protrusions 31 and the transportation can be stabilized. As another embodiment, as shown in FIG. 8, the presser roll 19 may have a structure such that on both ends of the roll surface, notch grooves 37, 37, . . . gearing with protrusions 31, 31, . . . are provided in series.

In the embodiment of the present invention, between the unwinding reel 5 and the treatment part 13, an unwinding side dancer roll 21 is provided in order to apply a tension toward the unwinding side on the film carrier tape 3 by the self-weight.

Further, between the winding reel 7 and the treatment part 13, a winding side dancer roll 23 is provided in order to apply a tension toward the winding side on the film carrier tape 3 by the self-weight.

In FIG. 3, the unwinding side dancer roll 21 is abutted on the roll surface from the upper side with the film carrier tape 3 positioned between the unwinding reel 5 and the guide roll 9, and applies the self-weight. By this application, a tension on the unwinding side, namely a tension at the direction opposite to the transportation direction is applied to the film carrier tape 3 positioned between the guide roll 9 and the guide roll 11.

Further, the winding side dancer roll 23 is abutted on the roll surface from the upper side with the film carrier tape 3 positioned between the winding reel 7 and the guide roll 11, and applies the self-weight. By this application, a tension on the winding side, namely a tension at the transportation direction is applied to the film carrier tape 3 positioned between the guide roll 9 and the guide roll 11.

Furthermore, the apparatus is formed so that the self-weight of the winding side dancer roll 23 is heavier than the self-weight of the unwinding side dancer roll 21. Therefore, to the film carrier tape 3, a tension on the winding side, namely at the transportation direction, is applied as the balance of the tensions (tensile strength) at the opposite directions each other applied by the self-weight caused by each of the dancer rolls. By this application, as shown in FIG. 4, the film carrier tape 3 is transported in such a condition that the gear protrusions 31, 31, . . . of the drive gear 17 are abutted to the ends 46 on the side opposite to the transportation direction of the sprocket holes 40, 40 . . . or they are not abutted to the ends 44 on the transportation direction side.

Accordingly, the sprocket holes 40 are engaged with the gear protrusions 31 in a condition that there is a gap in the transportation direction side thereof so that the gear protrusions 31 do not meet with the ends 44 in the transportation direction side in coming out the engagement by rotation of the drive gear 17. On this account, the film carrier tape 3 can be stably transported without damaging the film carrier tape 3, that is, this apparatus does not cause the following problems that whenever the engagement thereof comes out and the gear protrusions 31 is rubbed with the end parts 44 on the transportation direction side, or noises such as crunch or the like are caused, or the end parts 44 are deformed or broken.

In the unwinding side dancer roll 21 and the winding side dancer roll 23, guides are provided by forming grooves having the almost same width as the width of the film carrier tape 3 along the both ends in the roll width direction, so that the film carrier tape 3 does not come out, and thereby, the unwinding side dancer roll 21 and the winding side dancer roll 23, as they are, can give the self-weight to the film carrier tape 3 without using an appropriate assistant means. The force of the balance between the tension on the unwinding side applied by the unwinding side dancer roll 21 with the self-weight and the tension on the winding side applied by the winding side dancer roll 23 with the self-weight, which depends on the apparatus structure, is in terms of weight preferably from 20 to 300 g, more preferably 40 to 80 g from the viewpoint of obtaining the effect of the present invention.

The embodiment of the present invention has a structure such that as the unwinding side tension applying means for applying a tension on the unwinding side and the winding side tension applying means for applying a tension on the winding side, the dancer rolls 21 and 23 are used and a tension is applied to the film carrier tape 3 by the self-weight. However, the present invention should not be limited by the above structure. Namely, it is possible to employ an appropriate means other than the dancer roll as the structure for giving a tension to the film carrier tape 3 by the self-weight.

Furthermore, the present invention is not limited by the structure that a tension is applied to the film carrier tape 3 by the self-weight, and the effect of the present invention can be attained by such a structure that the tension applied by the winding side tension applying means is larger than the tension applied by the unwinding side tension applying means. For example, it is possible to employ the following structure. A pair of the upper and lower rolls (winding side tension applying means) is disposed with sandwiching the film carrier tape 3 at the position of the downstream side in the transportation direction to the drive gear 17, the both end sides in the width direction of the film carrier tape 3 (sprocket holes 40 neighbor) are abutted to the roll surface so as to slip each other, the film carrier tape 3 is held and drawn in the transportation direction with the force capable of driving the roll in the transportation direction, and thereby a tension is applied. Furthermore, in place of the pair of the upper and lower rolls, a pair of upper and lower plate-like members is disposed, the film carrier tape 3 is sandwiched with the plate-like members from the upper side and the lower side and transported with pressing, the film carrier tape 3 is held and drawn in the transportation direction with the force capable of driving the plate-like members in the transportation direction, and thereby a tension is also applied.

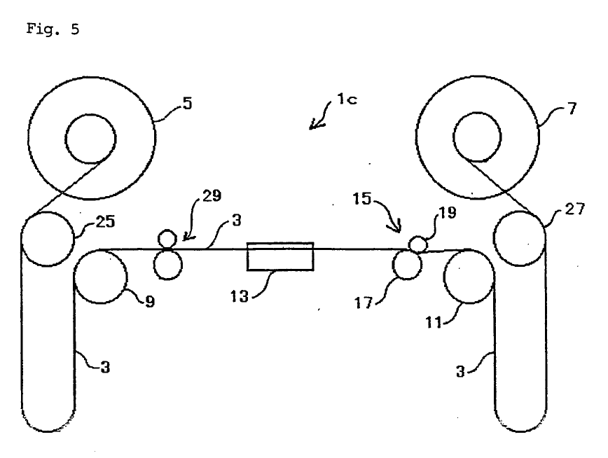

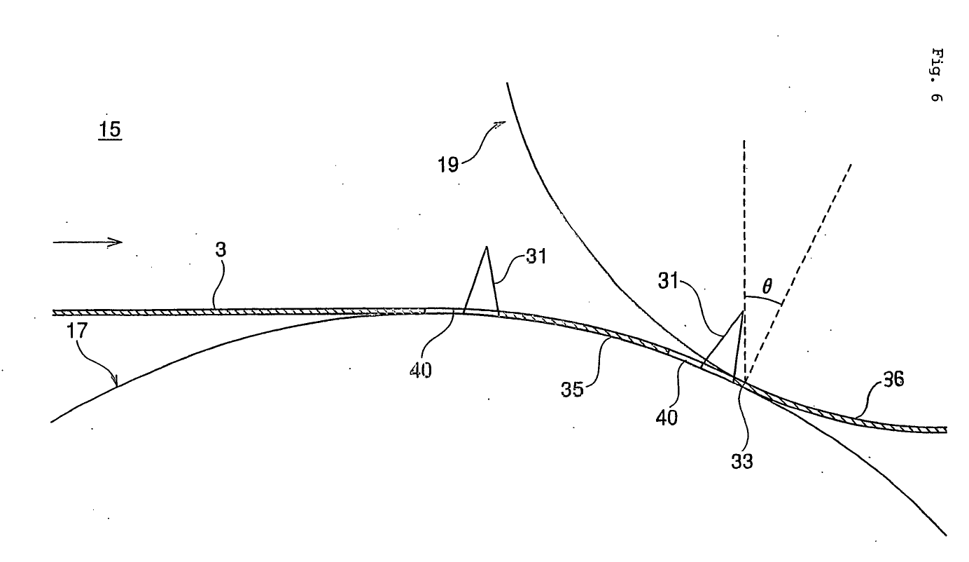

The transportation apparatus 1c for a film carrier tape for mounting electronic components disclosed in the embodiment as shown in FIG. 5 is characterized by having the structure of the transportation driving part 15 as shown in FIG. 6. The referential numeral 29 in FIG. 5 shows a back tension part and the back tension part comprises a pair of rolls provided so that the roll surfaces sandwich the film carrier tape 3 from upper and lower sides. The film carrier tape 3 is held with each of the roll surfaces and pressed, and thereby a tension at the direction opposite to the transportation direction is applied on the film carrier tape 3, which is transported by driving of the transportation driving part 15, so that the film carrier tape 3 is stably and straightly transported.

As shown in FIG. 6, in the present embodiment, the presser roll 19 is disposed in such a state that the shaft of the presser roll 19 is tilted with a certain angle in the transportation direction with respect to the shaft of the drive gear 17.

From this disposition, the film carrier tape 3 is abutted with the drive roll surface 35 of the drive gear 17 at a surface on the upstream side of the transportation direction from the contact point 33 between the drive gear 17 and the presser roll 19. Furthermore, the film carrier tape 3 is abutted with the presser roll surface 36 of the presser roll 19 at a surface on the downstream side of the transportation direction from the contact point 33 between the drive gear 17 and the presser roll 19.

As is clear from the above, since the film carrier tape 3 is contacted with the drive roll surface 35 and the presser roll surface 36 not at a point but at a surface and thereby the contact area is wide, the film carrier tape can be transported stably. For example, it is possible to prevent the sprocket holes 40, which are also used for positioning, or wiring patterns, from damage caused by the conditions that the film carrier tape 3 is shifted and thereby the gear protrusions 31 engaged with the sprocket holes 40 catch in the film carrier tape 3.

In disposing the presser roll 19, the shaft of the presser roll 19 is tilted at an angle θ in the transportation direction with respect to the shaft of drive gear. The angle θ, which depends on the apparatus structure, is preferably from 5 to 45 degree, more preferably 15 to 20 degree from the viewpoint of obtaining the effect of the present invention.

The transportation apparatus 1a for the film carrier tape for mounting electronic components in the embodiment as shown in FIG. 1 is equipped with the dancer rolls 21 and 23, as similar to the embodiment as shown in FIGS. 3 and 4 and has a structure such that the shaft of the roll 19 is tilted at a certain angle in the transportation direction with respect to the shaft of the drive gear 17, as similar to the embodiment as shown in FIGS. 5 and 6.

From the this structure, as shown in FIG. 2, the film carrier tape 3 can be transported in such a condition that the gear protrusions 31, 31, . . . of the drive gear 17 are abutted with the end part 46 opposite to the transportation direction of the sprocket holes 40, 40, . . . or in such a condition that they are not abutted with the end 44 of the transportation direction side, and in such a condition that the film carrier tape 3 is abutted with the drive roll surface 35 and the presser roll surface 36 at a surface as described above.

Therefore, since the gear protrusions 31 and the sprocket holes 40 are engaged with a gap in the transportation direction side, in coming out the engagement by rolling of the drive gear 17, the gear protrusions 31 do not meet with the end 44 on the transportation direction side. Further, since the film carrier tape 3 is contacted with the drive roll surface 35 and the presser roll surface 36 not at a point but at a surface, and the contact surface is wide, the film carrier tape can be stably transported. For example, it is possible to prevent the sprocket holes 40, which are also used for positioning, or wiring patterns from damage caused by catching the gear protrusions 31 engaged with the sprocket holes 40 in the film carrier tape 3.

The force of the balance between the tension in the unwinding side applied by the unwinding side dancer roll 21 with the self-weight and the tension in the winding side applied by the winding side dancer roll 23 with the self-weight, which depends on the apparatus structure, is in terms of weight preferably from 20 to 300 g from the viewpoint of obtaining the effect of the present invention. In disposing the presser roll 19, the shaft of the presser roll 19 is tilted at an angle θ in the transportation direction with respect to the shaft of the drive gear. The angle θ, which depends on the apparatus structure, is preferably from 5 to 45 degree from the viewpoint of obtaining the effect of the present invention.

The embodiments of the present invention have been described above. However, the present invention is not limited by these embodiments, and the embodiments can be transformed and modified variously. The transportation apparatus and the transportation process according to the present invention can be used for failure unit determination treatment or marking treatment for failure units in the inspection step for the film carrier tape 3 for mounting electronic components in the treatment part 13. Furthermore, the treatment in the treatment part 13 may include the production steps for the film carrier tape 3, for example, exposure, solder resist coating treatment, plating treatment and the like. The transportation apparatus and the transportation process can be also used to carry out these treatments.

1. A transportation apparatus for a film carrier tape for mounting electronic components which apparatus comprises:
an unwinding reel for unwinding a film carrier tape for mounting electronic components,
a treatment part for treating a prescribed treatment to the film carrier tape unwound from the unwinding reel,
a winding reel for winding the film carrier tape treated in the treatment part, and
a transportation driving part equipped with a drive gear having a plurality of gear protrusions for transporting the film carrier tape by engaging with sprocket holes formed on the film carrier tape, and further comprises
an unwinding side tension applying means for applying a tension on the unwinding side to the film carrier tape which means is provided between the unwinding reel and the treatment part, and
a winding side tension applying means for applying a tension on the winding side to the film carrier tape which means is provided between the winding reel and the treatment part,
wherein the tension applied by the winding side tension applying means is larger than the tension applied by the unwinding side tension applying means, and thereby
the film carrier tape is transported in such a condition that the gear protrusions of the drive gear are not abutted with the edges of the transportation direction side in the sprocket holes of the film carrier tape.

2. The transportation apparatus for a film carrier tape for mounting electronic components according to claim 1 wherein the unwinding side tension applying means and the winding side tension applying means are formed so that a tension is applied by the self-weight to the film carrier tape and the self-weight of the winding side tension applying means is heavier than the self-weight of the unwinding side tension applying means and thereby the film carrier tape is transported in such a condition that the gear protrusions of the drive gear are not abutted with the edges of the transportation direction side in the sprocket holes of the film carrier tape.

3. The transportation apparatus for a film carrier tape for mounting electronic components according to claim 2 wherein the unwinding side tension applying means and the winding side tension applying means each are a dancer roll.

4. A transportation apparatus for a film carrier tape for mounting electronic components which apparatus comprises:
an unwinding reel for unwinding a film carrier tape for mounting electronic components,
a treatment part for treating a prescribed treatment to the film carrier tape unwound from the unwinding reel,
a winding reel for winding the film carrier tape treated in the treatment part, and
a transportation driving part equipped with a drive gear having a plurality of gear protrusions for transporting the film carrier tape by engaging with sprocket holes formed on the film carrier tape,
wherein the drive gear is equipped with a drive roll surface and
the transportation driving part is equipped with a presser roll having a presser roll surface capable of holding the film carrier tape by abutting with the drive roll surface of the drive gear,
the presser roll is disposed in such a state that the shaft of the presser roll is tilted with a predetermined angle in the transportation direction with respect to the shaft of the drive gear, and thereby
the film carrier tape is transported in such a condition that the film carrier tape is abutted with the drive roll surface of the drive gear at a surface on the upstream side in the transportation direction from the contact point of the drive gear with the presser roll, and
the film carrier tape is abutted with the presser roll surface of the presser roll at a surface on the downstream side in the transportation direction from the contact point of the drive gear with the presser roll.

5. A transportation apparatus for a film carrier tape for mounting electronic components which apparatus comprises:
an unwinding reel for unwinding a film carrier tape for mounting electronic components,
a treatment part for treating a prescribed treatment to the film carrier tape unwound from the unwinding reel,
a winding reel for winding the film carrier tape treated in the treatment part, and
a transportation driving part equipped with a drive gear having a plurality of gear protrusions for transporting the film carrier tape by engaging with sprocket holes formed on the film carrier tape, and further comprises
an unwinding side tension applying means for applying a tension on the unwinding side to the film carrier tape which means is provided between the unwinding reel and the treatment part, and
a winding side tension applying means for applying a tension on the winding side to the film carrier tape which means is provided between the winding reel and the treatment part,
wherein the tension applied by the winding side tension applying means is larger than the tension applied by the unwinding side tension applying means, and thereby
the film carrier tape is transported in such a condition that the gear protrusions of the drive gear are not abutted with the edges of the transportation direction side in the sprocket holes of the film carrier tape, and further,
the drive gear is equipped with a drive roll surface and
the transportation driving part is equipped with a presser roll having a presser roll surface capable of holding the film carrier tape by abutting with the drive roll surface of the drive gear,
the presser roll is disposed in such a state that the shaft of the presser roll is tilted with a predetermined angle in the transportation direction with respect to the shaft of the drive gear, and thereby
the film carrier tape is transported in such a condition that the film carrier tape is abutted with the drive roll surface of the drive gear at a surface on the upstream side in the transportation direction from the contact point of the drive gear with the presser roll, and
the film carrier tape is abutted with the presser roll surface of the presser roll at a surface on the downstream side in the transportation direction from the contact point of the drive gear with the presser roll.

6. The transportation apparatus for a film carrier tape for mounting electronic components according to claim 5 wherein the unwinding side tension applying means and the winding side tension applying means are formed so that a tension is applied by the self-weight to the film carrier tape and the self-weight of the winding side tension applying means is heavier than the self-weight of the unwinding side tension applying means and thereby the film carrier tape is transported in such a condition that the gear protrusions of the drive gear are not abutted with the edges of the transportation direction side in the sprocket holes of the film carrier tape.

7. The transportation apparatus for a film carrier tape for mounting electronic components according to claim 6 wherein the unwinding side tension applying means and the winding side tension applying means each are a dancer roll.

8. A process for transporting a film carrier tape for mounting electronic components using a transportation apparatus for a film carrier tape for mounting electronic components which apparatus comprises:
an unwinding reel for unwinding a film carrier tape for mounting electronic components,
a treatment part of treating a prescribed treatment to the film carrier tape unwound from the unwinding reel,
a winding reel for winding the film carrier tape treated in the treatment part, and
a transportation driving part equipped with a drive gear having a plurality of gear protrusions for transporting the film carrier tape by engaging with sprocket holes formed on the film carrier tape, which process comprises the steps of:
applying a tension on the unwinding side to the film carrier tape by an unwinding side tension applying means provided between the unwinding reel and the treatment part,
applying a tension to the winding side to the film carrier tape by a winding side tension applying means provided between the winding reel and the treatment part,
wherein the tension applied by the winding side tension applying means is larger than the tension applied by the unwinding side tension applying means, and thereby
transporting the film carrier tape in such a condition that the gear protrusions of the drive gear are not abutted with the edges of the transportation direction side in the sprocket holes of the film carrier tape.

9. A process for transporting a film carrier tape for mounting electronic components using a transportation apparatus for a film carrier tape for mounting electronic components which apparatus comprises:
an unwinding reel for unwinding a film carrier tape for mounting electronic components,
a treatment part for treating a prescribed treatment to the film carrier tape unwound from the unwinding reel,
a winding reel for winding the film carrier tape treated in the treatment part, and
a transportation driving part equipped with a drive gear having a plurality of gear protrusions for transporting the film carrier tape by engaging with sprocket holes formed on the film carrier tape,
wherein the drive gear is equipped with a drive roll surface and
the transportation driving part is equipped with a presser roll having a presser roll surface capable of holding the film carrier tape by abutting with the drive roll surface of the drive gear,
the presser roll is disposed in such a state that the shaft of the presser roll is tilted with a predetermined angle in the transportation direction with respect to the shaft of the drive gear, and thereby
the film carrier tape is transported in such a condition that the film carrier tape is abutted with the drive roll surface of the drive gear at a surface on the upstream side in the transportation direction from the contact point of the drive gear with the presser roll, and
the film carrier tape is abutted with the presser roll surface of the presser roll at a surface on the downstream side in the transportation direction from the contact point of the drive gear with the presser roll.

10. A process for transporting a film carrier tape for mounting electronic components using a transportation apparatus for a film carrier tape for mounting electronic components which apparatus comprises:
an unwinding reel for unwinding a film carrier tape for mounting electronic components,
a treatment part for treating a prescribed treatment to the film carrier tape unwound from the unwinding reel,
a winding reel for winding the film carrier tape treated in the treatment part, and
a transportation driving part equipped with a drive gear having a plurality of gear protrusions for transporting the film carrier-tape by engaging with sprocket holes formed on the film carrier tape,
which process comprises the steps of:
applying a tension on the unwinding side to the film carrier tape by an unwinding side tension applying means provided between the unwinding reel and the treatment part,
applying a tension on the winding side to the film carrier tape by a winding side tension applying means provided between the winding reel and the treatment part,
wherein the tension applied by the winding side tension applying means is larger than the tension applied by the unwinding side tension applying means, and thereby
transporting the film carrier tape in such a condition that the gear protrusions of the drive gear are not abutted with the edges of the transportation direction side in the sprocket holes of the film carrier tape, and further,
the drive gear is equipped with a drive roll surface and
the transportation driving part is equipped with a presser roll having a presser roll surface capable of holding the film carrier tape by abutting with the drive roll surface of the drive gear,
the presser roll is disposed in such a state that the shaft of the presser roll is tilted with a predetermined angle in the transportation direction with respect to the shaft of the drive gear, and thereby
the film carrier tape is transported in such a condition that the film carrier tape is abutted with the drive roll surface of the drive gear at a surface on the upstream side in the transportation direction from the contact point of the drive gear with the presser roll, and
the film carrier tape is abutted with the presser roll surface of the presser roll at a surface on the downstream side in the transportation direction from the contact point of the drive gear with the presser roll.
